(19) United States
(12) Patent Application Publication
(10) Pub. No.: US 2026/0121380 A1
(43) Pub. Date: Apr. 30, 2026

(54) OPTICAL LINK WITH MODULATION OF VCSEL MODES

(71) Applicant: Volantis Semiconductor, Inc., Portland, OR (US)

(72) Inventor: Tapabrata Ghosh, San Francisco, CA (US)

(73) Assignee: Volantis Semiconductor, Inc., Portland, OR (US)

(21) Appl. No.: 19/223,614

(22) Filed: May 30, 2025

Related U.S. Application Data
(63) Continuation-in-part of application No. 19/222,606, filed on May 29, 2025.
Application No. 19/222,606 is a continuation-in-part of application No. 19/211,446, filed on May 19, 2025.
Application No. 19/211,446 is a continuation-in-part of application No. 19/210,116, filed on May 16, 2025.
Application No. 19/210,116 is a continuation-in-part of application No. 19/192,587, filed on Apr. 29, 2025.
Application No. 19/192,587 is a continuation-in-part of application No. 19/192,146, filed on Apr. 28, 2025.
Application No. 19/192,146 is a continuation-in-part of application No. 19/189,471, filed on Apr. 25, 2025.
Application No. 19/189,471 is a continuation-in-part of application No. 19/188,057, filed on Apr. 24, 2025.
Application No. 19/188,057 is a continuation-in-part of application No. 19/177,834, filed on Apr. 14, 2025.
Application No. 19/177,834 is a continuation-in-part of application No. 19/093,546, filed on Mar. 28, 2025.
Application No. 19/093,546 is a continuation-in-part of application No. 19/079,851, filed on Mar. 14, 2025.
Application No. 19/079,851 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/714,353, filed on Oct. 31, 2024.
(60) Provisional application No. 63/720,216, filed on Nov. 14, 2024.
(60) Provisional application No. 63/750,817, filed on Jan. 29, 2025.
(60) Provisional application No. 63/750,822, filed on Jan. 29, 2025.

(51) Int. Cl. H01S 5/183

(52) U.S. Cl. CPC H01S 5/18308; H01S 5/18394; H01S 2301/16

(57) ABSTRACT

A first circuit sends electrical data. The sent electrical data is targeted toward a second circuit. The electrical data is sent to a vertical-cavity surface-emitting laser (VCSEL), where the VCSEL comprises a multimodal VCSEL that supports one or more high-order transverse modes. A mode of the VCSEL is modulated. The modulating comprises altering current to the VCSEL. The modulating includes emitting, by the VCSEL, a mode-modulated beam (MMB). The MMB is based on the electrical data that was sent. The MMB is coupled optically to an optical medium. The optical medium is further coupled to a mode-dependent optical element (MDOE). The MDOE decodes the MMB into the electrical data that was sent. The electrical data that was decoded is delivered to a second circuit.

### RELATED APPLICATIONS

This application is a continuation-in-part of U.S. patent application “Optical Link With Polarization-Switched VCSEL Modulation” Ser. No. 19/222,606, filed May 29, 2025.

The U.S. patent application “Optical Link With Polarization-Switched VCSEL Modulation” Ser. No. 19/222,606, filed May 29, 2025 is also a continuation-in-part of U.S. patent application “Hierarchical Redundancy With Parallel Optical Links” Ser. No. 19/211,446, filed May 19, 2025.

The U.S. patent application “Hierarchical Redundancy With Parallel Optical Links” Ser. No. 19/211,446, filed May 19, 2025 is also a continuation-in-part of U.S. patent application “Waveguides Based On Nanoimprint Lithography On A Photonic Wafer Scale Interposer” Ser. No. 19/210,116, filed May 16, 2025.

The U.S. patent application “Waveguides Based On Nanoimprint Lithography On A Photonic Wafer Scale Interposer” Ser. No. 19/210,116, filed May 16, 2025 is also a continuation-in-part of U.S. patent application “Photonic Wafer-Scale Interposer With Mirrors Based on Nanoimprint Lithography” Ser. No. 19/192,587, filed Apr. 29, 2025.

The U.S. patent application “Photonic Wafer-Scale Interposer With Mirrors Based on Nanoimprint Lithography” Ser. No. 19/192,587, filed Apr. 29, 2025, is also continuation-in-part of U.S. patent application “Photonic Wafer-Scale Interposer With Micro Transfer Printed VCSELS And Back Side Power Delivery” Ser. No. 19/192,146, filed Apr. 28, 2025.

The U.S. patent application “Photonic Wafer-Scale Interposer With Micro Transfer Printed VCSELS And Back Side Power Delivery” Ser. No. 19/192,146, filed Apr. 28, 2025 is also a continuation-in-part of U.S. patent application “Photonic Wafer Scale Interposer With Integrated Crystallographic Etched Mirrors And Pre-Angled Light” Ser. No. 19/189,471, filed Apr. 25, 2025.

The U.S. patent application “Photonic Wafer Scale Interposer With Integrated Crystallographic Etched Mirrors And Pre-Angled Light” Ser. No. 19/189,471, filed Apr. 25, 2025, is also a continuation-in-part of U.S. patent application “Photonic Wafer Scale Interposer With Angled Beam Grating Couplers” Ser. No. 19/188,057, filed Apr. 24, 2025.

The U.S. patent application “Photonic Wafer Scale Interposer With Angled Beam Grating Couplers” Ser. No. 19/188,057, filed Apr. 24, 2025, is also a continuation-in-part of U.S. patent application “Back Side Power Delivery For Wafer-Scale Integration With An Isometric Grid Array With Compression Pins” Ser. No. 19/177,834, filed Apr. 14, 2025.

The U.S. patent application “Back Side Power Delivery For Wafer-Scale Integration With An Isometric Grid Array With Compression Pins” Ser. No. 19/177,834, filed Apr. 14, 2025, is also a continuation-in-part of U.S. patent application “Back Side Power Delivery For Wafer-Scale Integration With Laser Assisted Bonding” Ser. No. 19/093,546, filed Mar. 28, 2025.

The U.S. patent application “Back Side Power Delivery For Wafer-Scale Integration With Laser Assisted Bonding” Ser. No. 19/093,546, filed Mar. 28, 2025, is also a continuation-in-part of U.S. patent application “Photonic Wafer-Scale Interposer With Tapered Waveguides” Ser. No. 19/079,851, filed Mar. 14, 2025.

The U.S. patent application “Photonic Wafer-Scale Interposer With Tapered Waveguides” Ser. No. 19/079,851, filed Mar. 14, 2025, is also a continuation-in-part of U.S. patent application “Back Side Power Delivery For Wafer-Scale Integration With An Isometric Grid Compression Plate” Ser. No. 19/056,456, filed Feb. 18, 2025, which claims the benefit of U.S. provisional patent applications “Chiplet-Based Optical Wafer-Scale Network Switch” Ser. No. 63/750,817, filed Jan. 29, 2025, and “Wafer-Scale Integration Power Delivery With An Isotropic Conductive Adhesive” Ser. No. 63/750,822, filed Jan. 29, 2025.

The U.S. patent application “Back Side Power Delivery For Wafer-Scale Integration With An Isometric Grid Compression Plate” Ser. No. 19/056,456, filed Feb. 18, 2025, is also a continuation-in-part of U.S. patent application “Back Side Power Delivery For Wafer-Scale Integration With Solderless Modular Power Substrates” Ser. No. 19/023,647, filed Jan. 16, 2025, which claims the benefit of U.S. provisional patent applications “Cooling For Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Back Side Power Delivery For Wafer-Scale Integration With Solderless Modular Power Substrates” Ser. No. 19/023,647, filed Jan. 16, 2025 is also a continuation-in-part of U.S. patent application “Wafer-Scale Integration With A Stiffening Isometric Grid Array” Ser. No. 18/978,188, filed Dec. 12, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Wafer-Scale Integration With A Stiffening Isometric Grid Array” Ser. No. 18/978,188, filed Dec. 12, 2024 is also a continuation-in-part of U.S. patent application “Cold Plate Cooling For Wafer-Scale Integration With Back Side Modular Power Delivery” Ser. No. 18/958,107, filed Nov. 25, 2024, which claims the benefit of U.S. provisional patent applications “Cooling for Wafer-Scale Integration With Back Side Power Coupling” Ser. No. 63/714,353, filed Oct. 31, 2024, and “Back Side Wafer-Scale Power Delivery With An Anisotropic Conductive Film” Ser. No. 63/720,216, filed Nov. 14, 2024.

The U.S. patent application “Cold Plate Cooling For Wafer-Scale Integration With Back Side Modular Power Delivery” Ser. No. 18/958,107, filed Nov. 25, 2024, is also a continuation-in-part of U.S. patent application “Back Side Wafer-Scale Integration With Modular Power Delivery” Ser. No. 18/940,944, filed Nov. 8, 2024, which claims the benefit of U.S. provisional patent application “Cooling for Wafer-Scale Integration With Back Side Power Coupling” Ser. No. 63/714,353, filed Oct. 31, 2024.

Each of the foregoing applications is hereby incorporated by reference in its entirety.

### FIELD OF ART

This application relates generally to transmitting data and more particularly to an optical link with modulation of VCSEL modes.

### BACKGROUND

For centuries, humans have sought and developed techniques for communicating over distances beyond those that can be achieved by voice or gesture techniques alone. Ancient civilizations developed messaging or “mailing” techniques, which consisted of sending written messages by runner, or bird, among courier techniques. If the distance the message was to be carried was long, the route dangerous, or other factors limited the capabilities of a single courier, the messages could be transferred between couriers via relays. Since relaying messages by courier, on foot, or even on horseback could take hours, days, or longer, newer signaling systems were developed. One such system, developed by Claude Chappe in 1792, was based on a series of towers and signaling flags or semaphores. Messages could be sent from tower to tower based on positions of the flags. The system could also be used between ships at sea. An operator in a tower would read a message sent from another tower, then forward the message on to one or more other towers. While such a system worked well when operators could see from tower to tower or ship to ship, the system failed during poor visibility conditions such as in inclement weather or at night.

From the discovery of electromagnetic (EM) waves by James Maxwell in 1864 and the demonstration by Heinrich Hertz in 1888 that EM waves could propagate through space, the concept of using the EM waves for wireless communication took root. Guglielmo Marconi is credited with inventing the spark gap transmitter in 1895. His successful demonstration of wireless communication or “radio” over a mile in 1895, and across the Atlantic Ocean in 1901 proved that information could be sent quickly over even long distances. A wireless telephone was introduced in 1946 that enabled wireless telephonic communication between a vehicle and existing wired telephony system. Wireless telephony was significantly improved by transitioning from the old radio telephones to a cellular telephony system, beginning in the 1970s. This new concept significantly improved connectivity and greatly increased the number of simultaneous wireless telephone connections.

Wireless, highspeed communications continue to evolve. The old analog systems of the past were replaced by digital ones which enabled digital voice and data. The digital systems supported both simultaneous voice and data communication. Further, the digital systems were faster and more efficient than their analog antecedents. The digital systems have evolved through various generations or “Gs” and are currently transitioning to 5G. The mobile internet capabilities introduced by 3G, and enhanced by 4G, are with 5G capable of providing high bandwidth services such as video streaming and gaming in addition to voice and text. Further, even more simultaneous connections are supported. As wireless services advance, new technologies are being developed. Promising systems include millimeter-wave communication, quantum communication, and other systems such as low Earth orbit satellites. Further, light based systems, dubbed, “Li-Fi”, in conjunction with AI and machine learning, are proposed to improve communication efficiency and user experience.

### SUMMARY

Increases to processor performance continue to be demanded by a wide range of users. The performance increases are further driven by ever more computationally complex applications. These applications, such as artificial intelligence (AI) training and modeling, climate modeling, genome sequencing, and so on continue to stress current technologies including processors, system-on-chips (SoCs), accelerators, servers, memories, power delivery, cooling technologies, and so on. As a result, enhanced processing performance continues to be indicated. For example, present day large language model (LLM) training time can be measured in months, requiring that many processors and accelerators be operated 24×7. To further advance AI and other computationally intensive applications, additional and substantial improvements in processing will require further advances in all system components. For example, interconnections between processors, accelerators, memory, and so on, must keep pace with the ability of these processing elements to perform calculations by providing data at an appropriate time. Otherwise, these processing elements can stall. If the processing elements stall due to data starvation, then the overall processing result would be that little, if any, overall performance improvement. Communication bandwidth, transfer speed (latency), and power consumption are critical parameters when considering overall system performance. These parameters are gating ones, both in current day high performance systems and the systems that will be created in the future.

Disclosed techniques enable improved data transmissions. A first circuit sends electrical data. The electrical data is sent to a vertical-cavity surface-emitting laser (VCSEL). A mode of the VCSEL is modulated. The modulation causes the VCSEL to emit a mode-modulated beam (MMB). The MMB is based on the data that was sent by the first circuit. The MMB is coupled optically to an optical medium. The optical medium is further coupled to a mode-dependent optical element (MDOE). The MDOE decodes the MMB into the electrical data that was sent. The electrical data is delivered to a second circuit.

A method for transmitting data is disclosed comprising: sending electrical data, by a first circuit, to a vertical-cavity surface-emitting laser (VCSEL); modulating a mode of the VCSEL, wherein the modulating includes emitting, by the VCSEL, a mode-modulated beam (MMB), wherein the MMB is based on the electrical data that was sent; coupling optically the MMB to an optical medium, wherein the optical medium is further coupled to a mode-dependent optical element (MDOE); decoding, by the MDOE, the MMB into the electrical data that was sent; and delivering the electrical data that was decoded to a second circuit.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for an optical link with modulation of VCSEL modes.

FIG. 2 is a flow diagram for modulating transverse electromagnetic (TEM) modes in a VCSEL.

FIG. 3 is a cross-section of a VCSEL.

FIG. 4 is a diagram of transverse modes resulting from a VCSEL.

FIG. 5 is a block diagram of an optical link with modulation of VCSEL modes.

FIG. 6 is an apparatus for an optical link with modulation of VCSEL modes.

FIG. 7 is a system diagram for an optical link with modulation of VCSEL modes.

### DETAILED DESCRIPTION

Techniques for sending data using a mode-switched receiverless link are disclosed. Today's rapidly increasing demand for processing performance continues to push the envelope for processors as well as other system elements. To meet these demands, high performance systems-on-chip (SoCs) have been designed that can include processors, memories, switching elements, and so on. These SoC's can feature transistor counts in the tens of billions. Furthering the ability for system-level performance, accelerators, such as artificial intelligence (AI) accelerators and machine learning (ML) accelerators, have been designed to offload and speed up particularly computationally complex and taxing calculations. For example, today's large language models can rely on many such scaled-out accelerators to perform training and inferencing. As raw processing power increases, the need for additional bandwidth and speed to access memory elements also increases, leading to advancements such as HBM memories where memory dies can be stacked on a single substrate.

The relentless drive to enhance performance has also spurred innovation in methods for interconnecting system elements. Previously, simple bus architectures and standards such as the Peripheral Component Interconnect (PCI) enabled adequate bandwidth to prevent stalling of processor elements. However, as the data processing capabilities of these elements grew, thereby increasing their ability to process more data more efficiently, advanced methods of interconnect were developed. For example, high speed serial links such as PCI Express (PCIe) enabled Gigabit-per-second speeds by implementing multiple “lanes”. As processing power has continued to increase, optical communications provide a low power, high bandwidth alternative to wire-based techniques for transferring data between processing elements. For example, multimode fibers enable remarkably high bandwidth, short-reach optical links which can be used to communicated between sever racks, switches, storage, and so on.

Optical interconnection techniques have also been actively pursued to increase on-chip communications. For example, vertical-cavity surface-emitting lasers (VCSELS) can be used to generate light-based communication within a chip, a wafer, etc. The light-based communication provides lower latency and wider bandwidth compared with traditional metal paths, particularly when the metal paths are long. However, VCSELS have disadvantages which can limit their performance and increase power usage. Traditionally, current is used to modulate a VCSEL. That is, once light is emitted, the intensity of the light can be adjusted by adding additional current. The optical power difference required to recognize a “1” (e.g., “on”) as opposed to a “0” (e.g., “off”) can be described as the extinction ratio of the VCSEL. A high extinction ratio is helpful for signal quality, case of receiver sensing, and power usage. However, issues exist that can limit the effectiveness of VCSELS as an on-chip, on-wafer, on-interposer, etc. communication device. First, VCSELS can be associated with a threshold current, which is a minimum level of current that must be sent into the active area of the VCSEL before light can be emitted (e.g., the VCSEL lases). This minimum current can reduce the extinction ratio and increase power usage. Further, while optical power output (e.g., light intensity) of the VCSEL near the threshold can be linear, the optical power output can become non-linear as current is increased. Thus, modulating VCSEL intensity with current can lead to increased power usage in order to maintain a high extinction ratio, especially when many VCSELS are incorporated in a chip, wafer, interposer, and so on.

To address these issues, an optical link with modulation of VCSEL modes link is disclosed. Electrical data is sent by a first circuit to a vertical-cavity surface-emitting laser (VCSEL). The first circuit can comprise a first chiplet. A mode of the VCSEL is modulated. The mode can be based on altering current injected into the VCSEL. The VCSEL emits a mode-modulated beam (MMB). The MMB is based on the electrical data that was sent. The MMB is coupled optically to an optical medium. The coupling optically can be accomplished by a mirror, such as a TMAH-etched mirror, a grating coupler, and so on. The coupling can include angling the MMB that was emitted by the VCSEL. The angling can be based a micro-optical element (MOE) such as a micro lens, a diffractive optical element, a Fresnel lens, an asymmetric non-focusing optical device, and so on.

The optical medium is further coupled to mode-dependent optical element (MDOE). The MDOE can comprise a micro lens, a mode filter, a grating coupler, a mode multiplexor (MMUX), and so on. The MDOE decodes the MMB into the electrical data that was sent. For the case of MMUX, a mode beam splitter (MBS) can separate the MMB into at least two single mode optical signals. The MBS can be within the MMUX. The MBS can be based on a grating coupler, where the grating coupler can accomplish separating the at least two single mode signals. Each single mode optical signal can be interpreted by a unique photodiode to an electrical signal. The interpreting can result in at least two electrical signals. The at least two electrical signals can be assembled into a single electrical signal. The single electrical signal can be based the electrical data that was sent. The electrical data is delivered to a second circuit. The second circuit can comprise a second chiplet. In embodiments, the first circuit comprises a first chiplet and the second circuit comprises a second chiplet. The first chiplet, the second chiplet, and the VCSEL can be within a plurality of chiplets bonded to a front side of a photonic wafer-scale integrations interposer (PWSI). The PWSI can include a plurality of waveguides. The optical medium can comprise a waveguide within the plurality of waveguides. The optical medium can include a single-mode fiber.

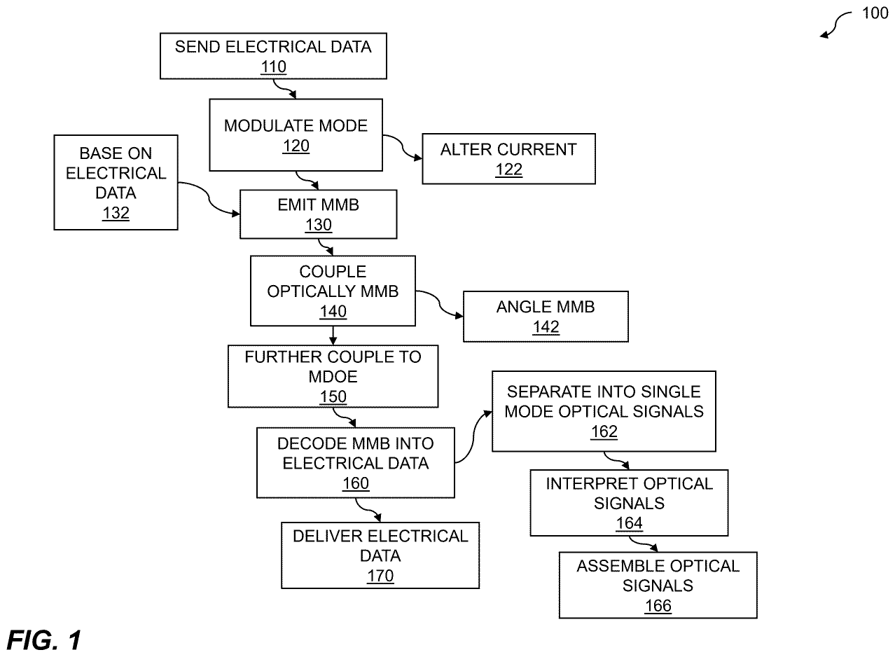

FIG. 1 is a flow diagram for an optical link with modulation of VCSEL modes. The flow 100 includes sending electrical data 110. Embodiments include sending electrical data, by a first circuit, to a vertical-cavity surface-emitting laser (VCSEL). The first circuit can be a circuit within a chip, a core, a chiplet, an SoC, a wafer, an interposer, etc. The first circuit can comprise a processor, chiplet, multi-core processor, memory controller, memory chip such as DDR or HBM, I/O chip, AI accelerator, switching chip, and so on. The first circuit and the VCSEL can be on the same or different circuit boards, interposers, wafers, etc. The sending can be accomplished using any means to communicate between chips. For example, the sending can be based on a routes (e.g., wires, waveguides, etc.) on a printed circuit board, a bus interface, a wireless communication protocol such as Bluetooth™, metal layers on a wafer or wafer interposer, metal line within a chip, and so on. The electrical data can comprise serialized data, data packets, handshaking signals, etc. A VCSEL can be a semiconductor laser fabricated on a chip. The fabrication can be based on gallium arsenide or another suitable material. The VCSEL can emit light in a perpendicular direction to the chip. The direction can be up (e.g., away from the chip) or down (e.g., into the chip). When light is emitted down, a window or aperture can be provided so that the light can escape through the back of the chip. To aid projection of the light, the substrate of the chip can be thinned. The light that is emitted can be coherent light that is in a wavelength range, such as 850 nm-950 nm. Other ranges are possible. Other surface-emitting light sources can be used, such as a laser diode, an LED, and so on.

The flow 100 includes modulating a mode 120 of the VCSEL. Embodiments include modulating a mode of the VCSEL, wherein the modulating includes emitting, by the VCSEL, a mode-modulated beam (MMB), wherein the MMB is based on the electrical data that was sent. Modulation can include adjusting properties of light emission of the VCSEL to encode optical data. For example, adjusting the current applied to an active region of the VCSEL can turn light emission on and off. When the current is below a threshold, lasing action can be stopped. When current levels return to a level exceeding the threshold, lasing can re-start. The detection of a presence or absence of light emitted from the VCSEL can be used to encode a “1” or “0” in the form of a light wave. As current is increased, a brightness, or optical power, of the VCSEL can be increased. Modulation can also include changing properties of the light that is emitted. For example, modulation can include a polarization of light emitted by the VCSEL, a wavelength of light emitted from the VCSEL, an intensity of light emitted from the VCSEL, and so on.

The modulation can include changing a mode of the light emitted by the VCSEL. Various altered currents that can be injected into the VCSEL can change the mode of the light emitted by the VCSEL. Modes can refer to an orientation of an oscillating light wave. In a usage example, the modes include transverse electromagnetic (TEM) modes. For TEM modes, the electric field and the magnetic fields are normal to, or perpendicular to, the direction of propagation of a wave. That is, there is no longitudinal electric field nor longitudinal magnetic field. TEM_{xy} can refer to a number of intensity nodes (or minima) in the x and y directions across the beam's transverse plane. Example TEM modes can include TEM₀₀, TEM₁₀, and TEM₀₁. The TEM₀₀ mode can include a fundamental mode, while the TEM₁₀ mode and the TEM₀₁ mode can include higher order modes.

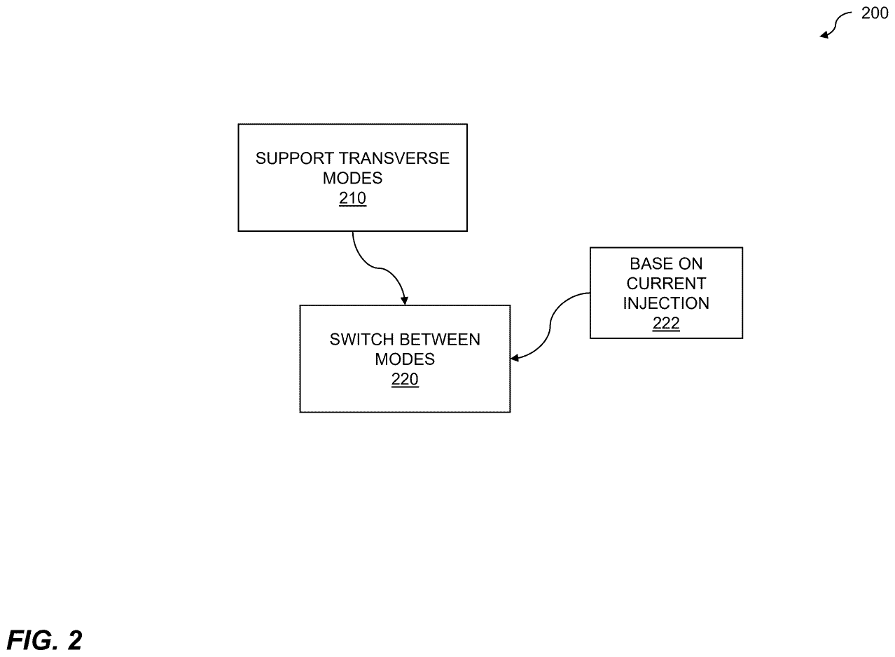

Various methods of VCSEL modulation can change the mode of light that is emitted by the VCSEL. In embodiments, the modulating comprises altering current 122 to the VCSEL. The altering current can include injecting or not injecting current; changing a DC value of current; changing an AC frequency and magnitude of current, and so on. The mode of light can be altered by changing current to the VCSEL. In some embodiments, the VCSEL comprises an inverted aperture VCSEL. An inverted aperture VCSEL can include a VCSEL in which the aperture from which the light is emitted is fabricated using an inverted relief technique, an inverted p-n junction configuration, and so on. The inverted aperture VCSEL can achieve improved mode control characteristics. The inverted aperture VCSEL can be used to modulate a mode of the VCSEL such as described above and can be used to encode optical data. In other embodiments, the VCSEL comprises a multimodal VCSEL (described in further detail in FIG. 2). In embodiments, the multimode VCSEL supports one or more high order transverse modes. In embodiments, the modulating comprises switching between a lower order transverse mode and a high order transverse mode within the one or more high order transverse modes. In embodiments, the switching is based on current injection. In some embodiments, a fundamental mode of the VCSEL comprises a higher order mode than a non-fundamental mode.

The flow 100, includes emitting, by the VCSEL, a mode-modulated beam (MMB) 130. An MMB can result from modulating the mode of the VCSEL as described above. The MMB can comprise an optical signal whose mode changes over time, thus encoding optical information. The MMB can be based on time-division multiplexing (TDM). TDM can be a multiplexing technique that can be used to include different modes emitted by a VCSEL, as described above, into a single optical signal by allocating specific time slots for each modulation. Later, the mode of the beam can be sensed, allowing for the decoding of the information that is sent. The decoding can be based on time-division demultiplexing (TDDM), which can interpret the optical signal based on the time slots that were established. Recall that electrical data is sent by a first circuit to a VCSEL. The electrical data can be used to modulate a mode of the VCSEL by disclosed techniques, resulting in an MMB sent from the VCSEL. Thus, in the flow 100, the MMB is based on the electrical data that was sent 132.

The flow 100 includes coupling optically the MMB 140. Embodiments include coupling optically the MMB to an optical medium, wherein the optical medium is further coupled to a mode-dependent optical element (MDOE). An optical medium can be any material, space, etc. that allows an optical signal, such as an MBM, to propagate. In embodiments, the optical medium comprises a waveguide. The waveguide can include a waveguide within a wafer, an interposer, and so on. Other optical mediums can be used. In a usage example, a fiberoptic cable is used as an optical medium to send an optical signal from a transmitter to a receiver. In embodiments, the optical medium comprises a single mode fiber. The single mode fiber can maintain fidelity of one or more TEM modes associated with the MMB. In embodiments, the first circuit comprises a first chiplet, wherein the second circuit comprises a second chiplet, wherein the first chiplet, the second chiplet, and the VCSEL are within a plurality of chiplets bonded to a front side of a photonic wafer-scale interposer (PWSI), wherein the PWSI includes a plurality of waveguides and wherein the optical medium comprises a waveguide within the plurality of waveguides. The optical medium can comprise a waveguide within the plurality of waveguides. Recall that the VCSEL can emit optical signals, such as the MMB, in a vertical direction. The vertical direction can be down, toward the substrate (and the PWSI to which a VCSEL can be bonded). A waveguide within the PWSI can be oriented horizontally or substantially horizontally. Thus, the MMB can be coupled to the waveguide in order for it to propagate along the waveguide to another chiplet bonded to the PWSI, such as the second chiplet.

In embodiments, the coupling optically is based on a grating coupler. The grating coupler can diffract light at specific frequencies, input angles, etc. thereby providing efficient transfer of light at a specific frequency or frequencies into or out of a waveguide. To aid the coupling to a grating coupler, the MMB emitted from the VCSEL can be angled 142. Embodiments include angling the MMB that was emitted by the VCSEL, wherein the angling is based on a micro-optical element (MOE). The MOE can be based on one or more optical techniques. For example, the MOE can comprise a micro lens. The micro lens can be coupled to the VCSEL which can pre-angle the emitted light. The MOE can comprise a diffractive optical element. The diffractive optical element can create a light phase profile that can focus, shape, or split the emitted light. The MOE can include a Fresnel lens. The Fresnel lens can use concentric grooves or rings to focus the emitted light. The MOE can include an asymmetric non-focusing optical device. The asymmetric non-focusing optical device can enable light to transmit through the device preferentially, where the light can pass through more easily in one direction than another direction. The asymmetric non-focusing optical device can couple light to a waveguide and can suppress a portion of reflected light back to the surface-emitting light source. Any number and/or types of MOEs can be used in conjunction with any number of VCSELS.

Other methods of coupling the PMB to an optical medium, such as a waveguide, can be implemented. In embodiments, the coupling optically is based on a mirror. The mirror can include a mirror within a wafer, an interposer, and so on. In a usage example, the coupling is based on a crystallographic etched mirror. The crystallographic etched mirror can comprise a tetramethylammonium hydroxide (TMAH) etched mirror. The TMAH mirror can reflect incoming light at a 54.74 degree angle to the waveguide. Other angles are possible with various crystallographic etched mirrors. A crystallographic etched mirror can operate in combination with a MOE, such as described above, which can be placed over or near an aperture of the VCSEL. For example, the MOE can pre-angle light from the VCSEL so that when the light is reflected by the TMAH mirror, it is efficiently coupled directly into the waveguide at 90 degrees, or sufficiently close to 90 degrees, from the light source. The coupling optically can be based on a bent waveguide. The bent waveguide can include a high containment region of a waveguide. The high containment waveguide can redirect the light while minimizing loss of light in the region of the bend of the waveguide. The coupling optically can be based on an off-axis diffractive lens. An off-axis diffractive lens can direct light at an angle with respect to the optical axis of the lens.

In the flow 100, the optical medium is further coupled to a mode-dependent optical element (MDOE) 150. A MDOE can be an optical element that interprets a mode state of an optical signal. The MDOE can be used to decode the MMB at the far end of the optical medium. The flow 100 includes decoding, by the MDOE, the MMB into the electrical data that was sent 160. The decoding can be based on time-division demultiplexing. The MDOE can be based on a variety of optical techniques. In some embodiments, the MDOE comprises a micro lens. The micro lens can angle a mode of light toward an optical elements such as an optical receiver. Different optical modes can be directed at different optical receivers. In some embodiments, the MDOE comprises a grating coupler. The grating coupler can decouple different modes of light from each other. Recall that a VCSEL can be modulated based on a mode, which can include a low order mode and a higher order mode. In some examples, the grating coupler allows only a low order mode to pass into the optical medium, thus optically encoding the MMB and sending it into the optical medium. In a usage example, the decoupled modes of light can be sent to optical receivers, where the optical receivers can convert the optical data to electrical data.

In other embodiments, the MDOE comprises a mode filter. A mode filter can enable passage of light with a mode that is compatible with the mode filter while substantially blocking light with modes that are incompatible with the mode filter. In a usage example, a first mode filter passes a light with a first mode, and a second mode filter passes light polarized with a second mode. In some embodiments, the MDOE comprises a mode multiplexor (MMUX). The MMUX can receive light that includes two or more modes. The received light can be separated into two or more beams, where each beam is based on a single mode. In embodiments, the decoding includes separating, by a mode beam splitter (MBS), the MMB into at least two single mode optical signals 162. The separating the modes can include directing the different modes at different angles toward an optical receiver associated with each mode. In embodiments, the MBS is based on a grating coupler. A variety of types of grating coupler can be used for the separating. In embodiments, the grating coupler comprises a two dimensional (2D) grating pattern. The 2D grating pattern can allow a fundamental mode of the VCSEL, such as TEM₀₀, to be coupled into one waveguide while a higher order mode, such as TEM₁₀, is coupled into another waveguide. The 2D grating pattern can enable mode-independent coupling of the MMB.

Embodiments include interpreting 164 each single mode optical signal within the at least two single mode optical signals, by a unique photodiode, to an electrical signal, wherein the interpreting results in at least two electrical signals. The electrical signals can be based on electrical values such as an amount of voltage or an amount of current. The electrical signals can include pulses, sinusoids, DC values, and the like. Embodiments include assembling the at least two electrical signals 166 into a single electrical signal, wherein the single electrical signal comprises the electrical data that was sent. The assembling the at least two electrical signals into a single electrical signal can be accomplished by retiming the electrical signals. In a usage example, the electrical signals can be retimed using a re-clocking technique.

The flow 100 includes delivering electrical data 170. Embodiments include delivering the electrical data that was decoded to a second circuit. As was the case for the first circuit, the second circuit can be a circuit within a chip, a core, a chiplet, an SoC, a wafer, an interposer, etc. The second circuit can comprise a processor, chiplet, multi-core processor, memory controller, memory chip such as DDR or HBM, I/O chip, AI accelerator, switching chip, and so on. The first circuit and the second circuit can be on the same or different circuit boards, interposers, wafers, chips, etc. The electrical data can be delivered to the second circuit using a variety of techniques. The delivery techniques can be based on using wire, interconnect, metal layers, and so on. The metal layers can include metal layers within a circuit board, a wafer, an interposer, and so on. The interposer can include a photonic wafer-scale interposer. The metal layers, which enable interconnection between and among circuits, chiplets, and other elements, can be fabricated on or within a circuit board, wafer, or interposer. As was the case for sending the data from the first circuit to the VCSEL, using the metal layers offers significant inter-chiplet communications speed due to short wire lengths, and reduced “parasitics” such as resistance, capacitance, and inductance. The second circuit can process the delivered data, forward the delivered data, etc.

Various steps in the flow 100 may be changed in order, repeated, omitted, or the like without departing from the disclosed concepts. Various embodiments of the flow 100, or portions thereof, can be included in an apparatus for transmitting data or system that is configured to transmit data.

FIG. 2 is a flow diagram for modulating transverse electromagnetic (TEM) modes in a VCSEL. Discussed previously and throughout, data is transmitted between a first circuit and a second circuit. The transmitting data is accomplished by sending electrical data, by a first circuit, to a vertical-cavity surface-emitting laser (VCSEL). A mode of the VCSEL, such as a TEM mode, is modulated. The modulating includes emitting, by the VCSEL, a mode-modulated beam (MMB). The modulating is based on altering current to the VCSEL. The MMB is based on the electrical data that was sent. The MMB is coupled optically to an optical medium. The optical medium can include a waveguide, a single mode fiber, and so on. The optical medium is further coupled to a mode-dependent optical element (MDOE). The MDOE can include a micro lens, a mode filter, a grating coupler, a mode multiplexor (MMUX), etc. The MDOE decodes the MMB into the electrical data that was sent. The electrical data that was decoded is delivered to a second circuit. Thus, the transmitting data is enabled by an optical link with modulation of VCSEL modes.

In embodiments, the VCSEL comprises a multimodal VCSEL. The modes that can be included in the multimodal VCSEL can include fundamental modes, lower order modes, high order modes, and so on. In a usage example, the supported modes can include a fundamental mode such as TEM₀₀. In embodiments, the multimode VCSEL supports one or more high order transverse modes 210. In a usage example, the one or more high order transverse modes can include TEM₁₀, or TEM₀₁. Other TEM modes can also be used. A variety of techniques can be used in order to modulate a mode of the VCSEL. In the flow 200, the modulating comprises switching between modes 220. In embodiments, the modulating comprises switching between a lower order transverse mode and a high order transverse mode within the one or more high order transverse modes. In a usage example, the lower order TEM can include TEM₀₀ and the high order transverse mode can include TEM₁₀. In a usage example, the switching between a lower order TEM and a high order TEM can represent switching between a binary zero and a binary one. In embodiments, a fundamental mode of the VCSEL comprises a higher order mode than a non-fundamental mode. In this case, a lower input current can induce the VCSEL to produce a higher order mode while a higher input current can cause the VCSEL to produce a low order mode. The switching between modes can be accomplished using one or more techniques. In embodiments, the switching is based on current injection 222. The current that can be injected can include a DC current, an AC current, a pulse or pulse train, and so on. The injected current can accomplish the modulating a mode of the VCSEL.

Various steps in the flow 200 may be changed in order, repeated, omitted, or the like without departing from the disclosed concepts. Various embodiments of the flow 200, or portions thereof, can be included in an apparatus for transmitting data or system that is configured to transmit data.

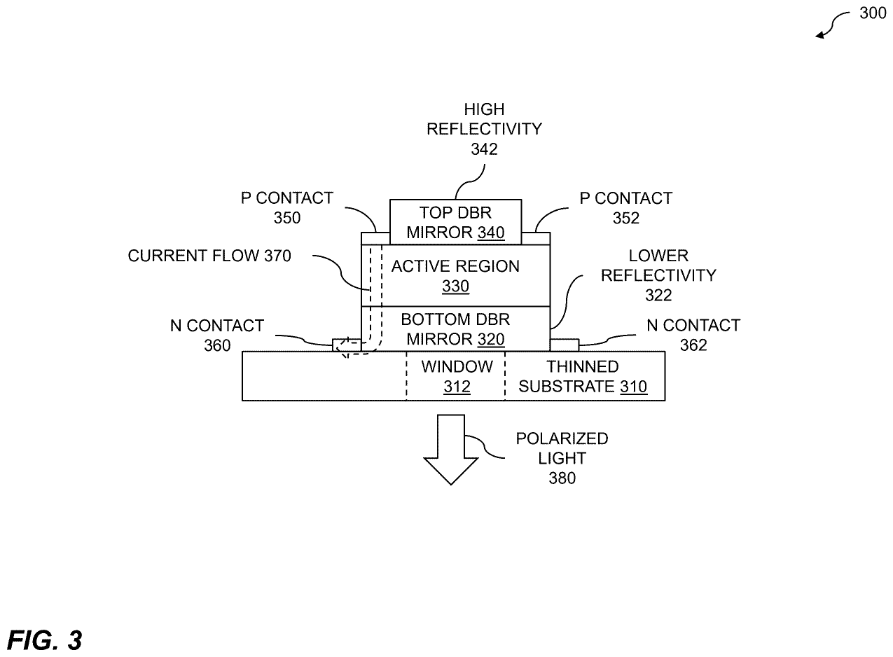

FIG. 3 is a cross-section of a VCSEL. A VCSEL enables optical links with modulation of VCSEL modes. A first circuit sends electrical data. The electrical data is sent to a vertical-cavity surface-emitting laser (VCSEL). A mode of the VCSEL is modulated. The modulating includes emitting, by the VCSEL, a mode-modulated beam (MMB). The MMB is based on the electrical data that was sent. The MMB is coupled optically to an optical medium. The optical medium is further coupled to a mode-dependent optical element (MDOE). The MDOE decodes the MMB into the electrical data that was sent. The electrical data that was decoded is delivered to a second circuit.

The block diagram 300 includes a thinned substrate 310. The thinned substrate can include a variety of materials suitable to fabricating a VCSEL. In a usage example, the substrate can include a gallium-arsenide (GaAs) substrate. Other materials that can be used for the substrate can include aluminum-gallium-arsenide (AlGaAs), germanium (Ge), sapphire, and so on. The substrate can be thinned to enable fabrication of an aperture or window 312. The thinning of the substrate can be accomplished by grinding, polishing, etching, and so on. Light in the form of a mode-modulated beam (MMB) can be emitted by the VCSEL. The light emitted by the VCSEL can exit the VCSEL by passing through the window in the thinned substrate.

The VCSEL can be capable of emitting one or more modes. In embodiments, the VCSEL comprises a multimodal VCSEL. In a usage example, the modes that can be emitted by the VCSEL can include transverse electromagnetic (TEM) modes. The TEM modes can include TEM₀₀, TEM₁₀, TEM₀₁, and so on The TEMs can include a variety of TEM modes. The TEM modes can include fundamental modes. In a usage example, a fundamental mode can include TEM₀₀. In embodiments, the multimode VCSEL supports one or more high order transverse modes. In a usage example, the high order transverse modes can include TEM₁₀ and TEM₀₁. While the fundamental TEM mode can include a Gaussian beam profile with a single intensity peak at the center, the high order TEM modes can include more complex intensity distributions that include a plurality of intensity peaks and nodes (e.g., an intensity of zero). The numbers associated with a TEM mode indicate an order of the mode in horizontal directions and vertical directions, respectively.

The VCSEL structure can include an active region that is placed between two reflective mirrors. The first mirror includes a first reflectivity, and the second mirror includes a second reflectivity. In a usage example, the two high reflectivity mirrors can be based on Distributed Bragg Reflectors (DBRs). These mirrors can be formed from multiple, alternating layers of materials, where the materials have different refractive indices. In the block diagram 300, a Distributed Bragg Reflector mirror can include a bottom mirror 320. The bottom mirror can include an n-Distributed Bragg Reflector. The bottom mirror can include a reflectivity that is lower 322 than a top mirror (described below). In a usage example, the reflectivity of the bottom DBR can include a reflectivity of 93 percent to 99 percent, or another suitable reflectivity. The n-Distributed Bragg Reflectors associated with the bottom mirror can be insulated from other layers in the block diagram by an oxide layer (not shown).

The block diagram 300 includes an active region 330. The active region can comprise a region in which light can be generated. The light that is generated is emitted by the VCSEL. The light can be generated using a variety of techniques. In a usage example, the active region can include a structure such as a quantum well structure, a quantum dot structure, and so on. The active region can be located within a laser cavity. The block diagram 300 can include an additional oxide layer (not shown) between the active region and a top DBR mirror. The oxide layer between the bottom mirror and the active area, and oxide layer between the active layer and the top mirror may or may not be present in the VCSEL. When present, the oxide layers can confine the light and electrical current within the active area of the VCSEL. The block diagram 300 includes a p-Distributed Bragg Reflector mirror 340. In the block diagram 300, the p-Distributed Bragg Reflector mirror comprises the top mirror of the VCSEL. The top mirror can include a high reflectivity 342. In a usage example, the reflectivity of the top DBR can include a reflectivity of 99.4 percent to 99.9 percent. Other suitable reflectivity values that can be associated with the bottom DBR and the top DBR can be implemented.

An electrical current is applied to the VCSEL in order for the VCSEL to lase and thus to emit coherent light. The applied electrical current can include a DC current, a pulsed current, and so on. The applied current further enables modulating a mode of the VCSEL In embodiments, the modulating comprises altering current to the VCSEL. The current that can be altered can include a direct current, a pulsed current, an alternating current, a symmetrical current, an asymmetrical current, etc. The altered current can modulate the light emitted by the VCSEL. In a usage example, the current is asymmetrical about the x-axis, that is, the asymmetrical current has a DC offset. The altering the current can cause the modulated light emitted by the VCSEL to include a mode. Altering the current can change the mode of the emitted light. In a usage example, the mode of the emitted light can include a Transverse Electromagnetic (TEM) mode. The TEM mode can include TEM₀₀, TEM₁₀, and TEM₀₁. The electrical current can be applied to the top p-contact. The p-contact can include a single contact, a ring contact, a “broken ring” contact where the ring is broken into two or more segments, and so on. In the block diagram 300, the top p-contact includes one or more p-contacts such as p-contact 350 and p-contact 352.

The electrical current can exit the bottom of the VCSEL via one or more n-contacts. The n-contacts can include a single contact, a ring contact, a broken ring contact, etc. In the block diagram 300, the one or more n-contacts include n-contact 360 and n-contact 362. In a usage example, a p-contact ring and an n-contact ring can be concentric broken rings. By altering the current that is applied to a p-contact and an n-contact one or more modes can be achieved. Recall that in embodiments, the modulating comprises switching between a lower order transverse mode and a high order transverse mode within the one or more high order transverse modes. The switching between a lower order or fundamental transverse mode and a high order transvers move can be controlled. In embodiments, the switching is based on current injection. The injected current can be adjusted by enabling and disabling the current, injecting an AC current, by switching polarity of the current, etc. In embodiments, a fundamental mode of the VCSEL comprises a higher order mode than a non-fundamental mode. The injected electrical current can flow 370 from a p-contact to an n-contact.

By accessing one or more portions of the p-contact ring and one or more portions of the n-contact ring various modes such as the TEM modes can be achieved. The modes generated within the multimode VCSEL are emitted through the window 312. Noted above, the VCSEL emits light 380. The light from the VCSEL can be emitted at an angle that can be substantially normal to a substrate, chip, PCB, interposer, etc. to which the VCSEL can be coupled. When there is a purpose for the light emitted by the VCSEL to be angled, then an optical device can be used. The purpose for angling the light can include enhancing optical coupling of the mode-modulated beam (MMB). Embodiments include angling the MMB that was emitted by the VCSEL, wherein the angling is based on a micro-optical element (MOE). The MOE can include a micro lens, a diffractive optical element, a Fresnel lens, an asymmetric non-focusing optical device, a mirror, and so on.

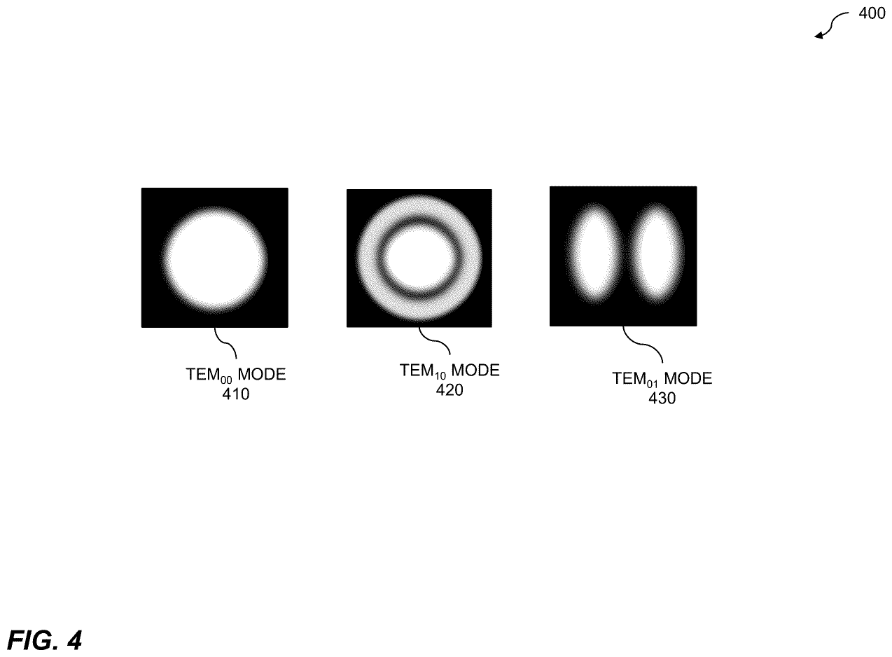

FIG. 4 is a diagram of transverse mode resulting from a VCSEL. Described previously, a mode of a VCSEL can be modulated by altering a current to the VCSEL. The mode can include a transverse electromagnetic (TEM) mode, where electric fields and magnetic fields are perpendicular to the direction of propagation. One or more TEM modes can be used to transmit data between electronic elements such as chips, chiplets, circuits, and so on, where the electronic elements can be collocated on a circuit board, wafer, interposer, and the like. The electronic elements can also be located on different boards, wafers, and interposers; located in different multiprocessors, located in different data racks or different datacenters, etc. The one or more transverse modes enable an optical link with modulation of VCSEL modes. An optical link that modulates VCSEL modes enables transmission of data between a first circuit and a second circuit. A first circuit sends electrical data. The electrical data is sent to a vertical-cavity surface-emitting laser (VCSEL). A mode of the VCSEL is modulated. The modulating can be based on asymmetric current injection. The modulation causes the VCSEL to emit a mode-modulated beam (MMB). The MMB is based on the electrical data that was sent by the first circuit. The MMB is coupled optically to an optical medium. The optical medium comprises a waveguide. The coupling optically is accomplished using a grating coupler or a mirror. The optical medium is further coupled to a mode-dependent optical element (MDOE). The MDOE decodes the MMB into the electrical data that was sent. The electrical data is delivered to a second circuit.

The FIG. 400 shows example transverse electromagnetic (TEM) waves. The TEM waves can result from modulating a mode of a VCSEL. The TEM modes, which can propagate via an optical medium such as a waveguide or an optical fiber, can transmit data between chips, chiplets, circuits, and so on. A variety of TEM modes can be modulated. In embodiments, the VCSEL comprises a multimodal VCSEL. The modulating modes of the VCSEL can be accomplished by an electric current. In embodiments, the modulating comprises altering current to the VCSEL. The altering current can include turning on a current and turning off a current; reversing a current; applying an asymmetric current, and so on. In embodiments, the multimode VCSEL supports one or more high order transverse modes. Thus, the modulating can be based on switching modes. In embodiments, the modulating comprises switching between a lower order transverse mode and a high order transverse mode within the one or more high order transverse modes.

A variety of TEMs can be used. In a usage example, a lower order or fundamental mode can include TEM₀₀ 410. TEM₀₀ comprises a Gaussian beam profile that includes a single peak in intensity at the center. One or more high order TEMs can be included in the variety of modulation modes. Two additional TEM modes can include TEM₁₀ 420 and TEM₀₁ 430. The subscripts associated with each TEM denotes an order of the mode in a horizontal direction and a vertical direction, respectively. The higher order modes can include a plurality of peak intensities and a plurality of nodes (e.g., an intensity substantially equal to zero). For TEM₁₀, there are two concentric intensity peaks. For TEM₀₁, there are two vertical parallel intensity peaks. Other TEM modes can be used. The various TEM modes can be used to represent binary values. In a usage example, a first TEM mode can represent a binary one while a second TEM mode can represent a binary zero. In another usage example, the presence of a TEM mode can represent a binary one, while the absence of a TEM mode can indicate a binary zero. In a further usage example, two different TEM modes can represent two different data streams. For the latter usage example, the TEM mode can be captured and re-clocked in order to decode electrical data such as serial electrical data that was sent by the first circuit. The decoded data can be delivered to a second circuit.

The result of modulating the VCSEL is a mode-modulated beam (MMB), where the MMB is based on electrical data sent by a first circuit to the VCSEL. The MMB can be coupled to an optical medium such as a waveguide, a single mode fiber, and so on. The optical medium is coupled to a mode-dependent optical element (MDOE) which decodes the MMB into the electrical data that was sent. The electrical data that was decoded is delivered to a second circuit, thereby completing transmitting data from the first circuit to the second circuit. The first circuit can comprise a first chiplet and the second circuit can comprise a second chiplet. The first chiplet and the second chiplet can be included on a PWSI.

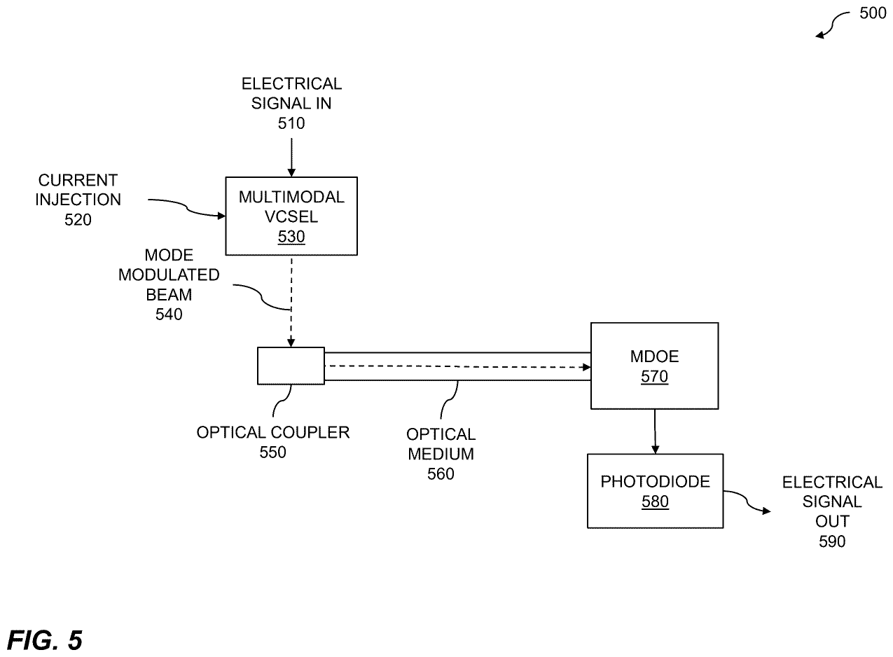

FIG. 5 is a block diagram of an optical link with modulation of VCSEL modes. An optical link that modulates VCSEL modes enables transmitting data between a first circuit, which can be a first chiplet and a second circuit, which can be a second chiplet. A first circuit sends electrical data. The electrical data is sent to a vertical-cavity surface-emitting laser (VCSEL). A mode of the VCSEL is modulated. The modulating can be based on asymmetric current injection. The modulation causes the VCSEL to emit a mode-modulated beam (MMB). The MMB is based on the electrical data that was sent by the first circuit. The MMB is coupled optically to an optical medium. The optical medium comprises a waveguide. The coupling optically is accomplished using a grating coupler or a mirror. The optical medium is further coupled to a mode-dependent optical element (MDOE). The MDOE decodes the MMB into the electrical data that was sent. The electrical data is delivered to a second circuit.

The block diagram 500 includes an electrical signal in 510. The electrical signal can represent data such as image data, video data, and audio data; artificial intelligence (AI) weights, biases, and data; and so on. The electrical signal can represent parallel data such as data set as bytes, words, etc. The electrical data can represent serial data. The block diagram 500 includes current injection 520. The current injection can comprise the basis for modulating a mode of a vertical-cavity surface-emitting laser (VCSEL) 530. In embodiments, the VCSEL comprises a multimodal VCSEL. In a usage example, the modulating the mode of the VCSEL can include a transverse electromagnetic (TEM) mode. Example TEM modes can include TEM₀₀, TEM₁₀, and TEM₀₁. In embodiments, the modulating comprises altering current to the VCSEL. The altering the current can include turning a current on and off; altering direction of a current; altering an amount of current; altering a period of the current; etc. The altering current can be applied to a VCSEL. The altering current can be applied to contacts associated with the VCSEL in order to emit a light mode at the output of the VCSEL. In the block diagram 500, the modulating includes emitting, by the VCSEL, a mode-modulated beam (MMB) 540, wherein the MMB is based on the electrical data that was sent. The MMB can be directed toward an optical coupler 550. The optical coupler can include a coupler on or within a circuit board, a wafer, an interposer, etc. The optical coupler can be based on a variety of optical elements, techniques, and so on. In a usage example, the coupling optically can be accomplished by a grating coupler. The grating coupler can include a periodic grating that can transfer the MMB with low loss into the optical medium. In another usage example, the coupling optically can be accomplished by a mirror. In a usage example, the mirror can include a nano-imprint lithography mirror. Embodiments include angling the MMB that was emitted by the VCSEL, wherein the angling is based on a micro-optical element (MOE) (not shown). The angling the MMB can be used to complement an angle associated with the coupling the MMB to the optical medium.

The block diagram includes an optical medium 560. The optical medium can include a media that is capable of transferring the MMB coupled to the optical medium by the optical coupler. The optical medium can include a waveguide on or within a wafer, an interposer, a chip, and so on. In embodiments, the optical medium comprises a single mode fiber. The block diagram 500 includes a mode-dependent optical element (MDOE) 570 to which the optical medium is further coupled. The MDOE can be based on a variety of optical elements, optical techniques, and so on. The MDOE can separate different modes of light from the MMB. The separated modes of light (e.g., optical data) can be decoded into electrical data that was sent by the first circuit. The MDOE can accomplish decoding the MMB based on a variety of decoding techniques. In embodiments, the MDOE comprises a micro lens. The micro lens can aid coupling modes of light to optical receivers such as photodiodes. In embodiments, the MDOE comprises a mode filter. A mode filter can pass a mode of light while substantially blocking or reflecting other modes of light. In embodiments, the MDOE comprises a grating coupler. The grating coupler can separate different modes from each other. In a usage example, the separated modes of light can be sent to optical receivers, where the optical receivers can convert the optical data to electrical data. In another usage example, the grating coupler can indicate when a first mode is active in the optical medium, which can comprise a “1”. The absence of the signal from the grating coupler can comprise a “0”. Clocking circuits, such as clock and data recovery (CDR) circuits, can synchronize the MMB with the receiving and/or decoding circuits.

In other embodiments, the MDOE comprises a mode filter. A mode filter can enable passage of light with a mode that is compatible with the mode filter while substantially blocking light with modes that are incompatible with the mode filter. In a usage example, a first mode filter passes light with a first mode. CDR circuits can again be used to coordinate an output to be sent to a second circuit. In another usage example, a second mode filter passes light comprising a second mode. In this case, the two signals can be reformed into a single signal. In further embodiments, the MDOE comprises a mode multiplexor (MMUX). The MMUX can receive light that includes two or more modes. The received light can be separated into two or more beams where each beam is based on a single mode. In embodiments, the decoding includes separating, by a mode beam splitter (MBS), the MMB into at least two single mode optical signals. In a usage example, the beam splitter can reflect light associated with a first mode and transmit light associated with a second mode. In embodiments, the MBS is within the MMUX.

Usage examples can include transforming each optical signal within the at least two optical signals with different modes, by a unique photodiode, to an electrical signal, wherein the transforming results in at least two electrical signals. The block diagram 500 includes a photodiode 580. More than one photodiode can be included, where each photodiode can transform or decode an optical signal into an electrical signal. In the block diagram 500, the MDOE decodes the MMB into the electrical data that was sent. The decoded MMB is sent as an electrical signal out 590. Discussed previously, each optical signal within the at least two optical signals with different modes is transformed by a unique photodiode to an electrical signal. The transforming results in at least two electrical signals. Further embodiments include assembling the at least two electrical signals into a single electrical signal, wherein the single electrical signal comprises the electrical data that was sent. The single electrical signal that includes the electrical data that was sent can be sent to a destination element such as a circuit a chiplet, etc. The destination element can include a processor, an AI accelerator chiplet, a switching chiplet, etc.

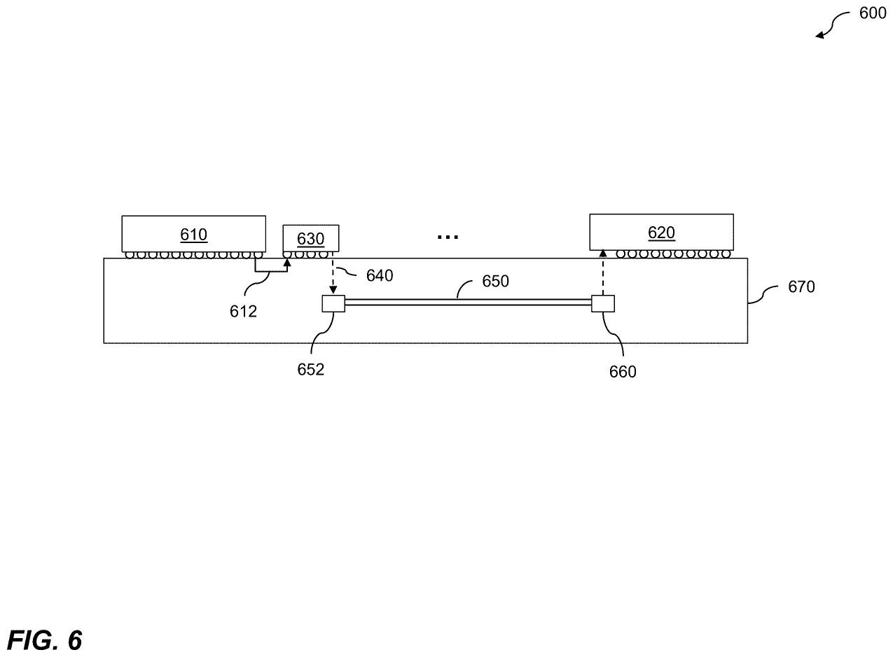

FIG. 6 is an apparatus for an optical link with modulation of VCSEL modes. An optical link can be established that enables transmitting data. The optical link can be used to send data from a first circuit, which can be a first chiplet, to a second circuit, which can be a second chiplet. The first circuit and the second circuit can be collocated on a circuit board, wafer, chip, interposer, etc.; located in different multiprocessors; located in different datacenters; and so on. In embodiments, the first circuit sends electrical data to a vertical-cavity surface-emitting laser (VCSEL). The VCSEL converts electrical data into optical data (e.g., light data). A mode of the VCSEL is modulated. The modulating includes emitting, by the VCSEL, a mode-modulated beam (MMB). The mode can include a transverse mode. The MMB is based on the electrical data that was sent. By coupling the modulated beam to an optical medium such as a waveguide, a fiber, and so on, the MMB is sent via the optical medium to a mode-dependent optical element (MDOE). The MDOE decodes the MMB to electrical data. The electrical data is delivered to the second circuit. The apparatus enables transmitting data using an optical link with modulation of VCSEL modes.

An apparatus is disclosed for transmitting data comprising: a first circuit, wherein the first circuit sends electrical data to a vertical-cavity surface-emitting laser (VCSEL), and wherein the VCSEL emits a mode-modulated beam (MMB); an optical medium, wherein the MMB is coupled optically to the optical medium via an optical coupler; a mode-dependent optical element (MDOE), wherein the MDOE is further coupled to the optical medium, wherein the MDOE decodes the MMB into the electrical data that was sent; and a second circuit, wherein the second circuit receives the electrical data that was sent.

The apparatus 600 includes a first circuit 610, wherein the first circuit sends electrical data to a vertical-cavity surface-emitting laser (VCSEL), and wherein the VCSEL emits a mode-modulated beam (MMB). In embodiments, the modulating comprises altering current to the VCSEL. The altering current can include enabling and disabling the current; providing a symmetrical current or an asymmetrical current; and so on. The first circuit, which can be a first chiplet, sends data to a second circuit, which can be a second chiplet 620 using the VCSEL and additional optical elements. The circuits, chiplets, etc. can be connected, attached, bonded, or otherwise coupled to a circuit board, a wafer, an interposer, and so on. The apparatus further includes a first vertical-cavity surface-emitting laser (VCSEL) 630. In some embodiments, the VCSEL comprises a multimodal VCSEL. In other embodiments, the VCSEL comprises an inverted aperture VCSEL. While two circuits and one VCSEL are shown, the apparatus can include any number of circuits and any number of VCSELs. The VCSELs can be of various types. The circuits can include chiplets, AI accelerators, switching chiplets, ASICS, I/O chips, and so on. The first circuit sends 612 electrical data to the VCSEL. The VCSEL emits a mode-modulated beam (MMB). The MMB 640 can include a beam with a plurality of modes. The modes can include TEM₀₀, TEM₁₀, and TEM₀₁. In a usage example, the MMB can include two modes, where one mode represents a logic one and the second mode represents a logic zero. In another usage example, two modes can represent two different serial data streams. The first circuit can send data to other surface-emitting light sources that can be modulated such as light emitting diodes (LEDs), laser diodes (LDs), and the like.

The MMB 640 emitted by the VCSEL is conveyed to an optical coupler 652. The apparatus 600 includes an optical medium 650, wherein the MMB is coupled optically to the optical medium via an optical coupler. The optical medium can include a low loss optical medium appropriate for sending the MMB. In embodiments, the optical medium comprises a waveguide. The optical medium can also include an optical fiber. In embodiments, the optical medium comprises a single mode fiber. The optical coupler can comprise a grating coupler. In embodiments, the coupling optically is accomplished by a grating coupler. The grating coupler can include a periodic grating that can transfer the PMB with low loss into the optical medium. The optical coupler can comprise a mirror. In embodiments, the coupling optically is based on a mirror. In a usage example, the mirror can include a nano-imprint lithography mirror. The coupling optically can be based on a bent waveguide. The bent waveguide can include a high-confinement bent waveguide which minimizes loss from the MMB as the MMB is coupled to the optical medium. The coupling optically can be based on an off-axis diffractive lens. An off-axis diffractive lens can focus light rays, such as those rays comprising the MMB, that are not aligned with the central axis of the lens. Embodiments include angling the MMB that was emitted by the VCSEL, wherein the angling is based on a micro-optical element (MOE). The angling the MMB can be used to complement an angle associated with the coupling the MMB to the optical medium. The angling can also compensate for variations in a wafer or interposer across the surface of the wafer or interposer. In a usage example, the MMB emitted by VCSEL can be pre-angled to an angle such as 9.74 degrees and a mirror such as a crystallographic etched mirror can include an angle, such as 54.74 degrees. The combination of pre-angling and angling can enable coupling the MMB to a waveguide at an angle substantially normal to an entrance aperture of the waveguide. The optical coupler can comprise a bent waveguide. The bent waveguide can include a high containment region of a waveguide. The high containment waveguide can redirect the light while minimizing loss of light in the region of the bend of the waveguide. The optical coupler can comprise an off-axis diffractive lens. An off-axis diffractive lens can direct light at an angle with respect to the optical axis of the lens.

The MOE can be based on one or more optical techniques. The MOE can comprise a micro lens. The micro lens can be coupled to a first surface-emitting light source such as the VCSEL, a laser diode (LD), an LED, and so on. The micro lens can pre-angle the emitted light. The MOE can comprise a diffractive optical element. The diffractive optical element can create a light phase profile that can focus, shape, or split the emitted light. The MOE can comprise a Fresnel lens. The Fresnel lens can use concentric grooves or rings to focus the emitted light. The MOE can comprise an asymmetric non-focusing optical device. The asymmetric non-focusing optical device can enable light to transmit through the device preferentially, where the light can pass through more easily in one direction than another direction. The asymmetric non-focusing optical device can couple light to an optical medium such as a waveguide and can suppress a portion of reflected light back to the surface-emitting light source.

The apparatus 600 includes a mode-dependent optical element (MDOE) 660, wherein the MDOE is further coupled to the optical medium, wherein the MDOE decodes the MMB into the electrical data that was sent. The MDOE can separate different modes of light from the MMB. The separated modes of light (e.g., optical data) can be decoded into electrical data that was sent by the first circuit. As described above and throughout, the MDOE can accomplish decoding based on a plurality of decoding techniques such as a grating coupler, a mode filter, a mode mux, and so on.

The apparatus 600 includes a second circuit which can be a second chiplet 620, wherein the second circuit receives the electrical data that was sent. The second circuit can receive the transmitted data that was sent by the first circuit. The first circuit and the second circuit can be located on a different or a common circuit board, a different or a common wafer, a different or a common rack, and so on. The first circuit and the second circuit can be remotely located with respect to each other. “Remotely located” can include locating the first circuit and the second circuit in separate circuit boards or wafers; separate multiprocessors, separate data racks, separate data centers, and so on. The first circuit, the second circuit, and the VCSEL can be coupled via an interface 670. The interface can comprise a board, a printed circuit board, an SoC, a wafer, a chip, a photonic wafer-scale interposer (PWSI), and so on. In embodiments, the first circuit comprises a first chiplet and the second circuit comprises a second chiplet. In embodiments, the first circuit comprises a first chiplet, wherein the second chiplet comprises a second chiplet, wherein the first chiplet, the second chiplet, and the VCSEL are within a plurality of chiplets bonded to a front side of a photonic wafer-scale interposer (PWSI), wherein the PWSI includes a plurality of waveguides and wherein the optical medium comprises a waveguide within the plurality of waveguides. The PWSI can enable high-speed communication between and among chiplets and VCSELs coupled to the PWSI. The PWSI can be configured to accomplish a variety of processing tasks. The PWSI can comprise an optical wafer-scale AI accelerator, wherein one or more chiplets within the plurality of chiplets comprise one or more artificial intelligence (AI) accelerators. The AI accelerators can be used for training AI models and machine learning (ML) models, executing the AI models and the ML models, and the like. The AI models and ML models can be applied to processing applications such as video and image processing; audio processing and voice recognition; etc. The PWSI can comprise an optical wafer-scale network switch, wherein one or more chiplets within the plurality of chiplets comprise one or more switching chiplets. The optical wafer-scale network switch can be used for accessing and transferring large amounts of data such as data associated with training AI models and ML models. The optical wafer-scale network switch can transfer data to be processed by the trained models. The optical wafer-scale network switch can include a topology such as a HyperX™ topology.

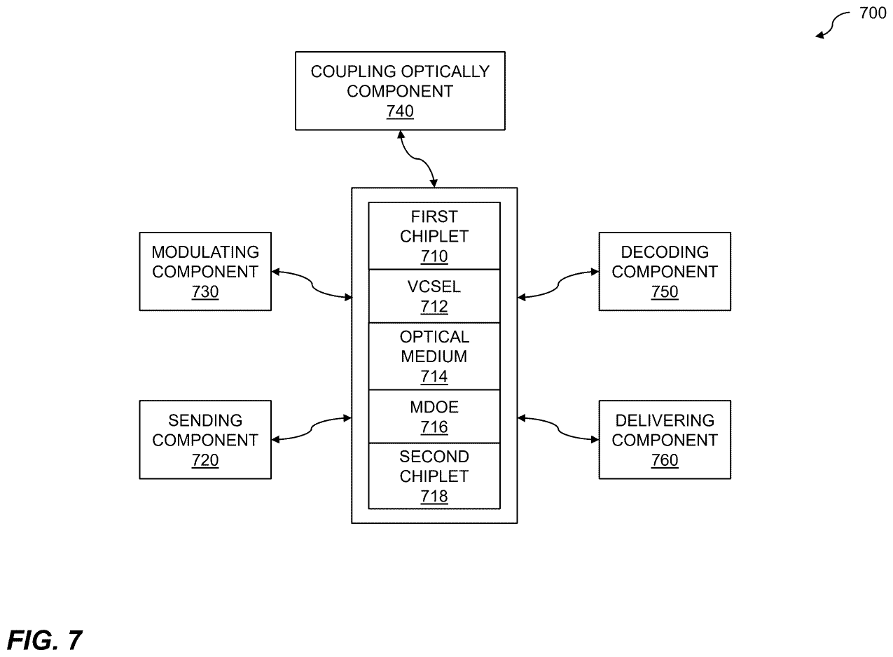

FIG. 7 is a system diagram for an optical link with modulation of VCSEL modes. A first circuit, which can be a first chiplet, sends electrical data. The electrical data is sent to a vertical-cavity surface-emitting laser (VCSEL). A mode of the VCSEL is modulated. The modulating includes emitting, by the VCSEL, a mode-modulated beam (MMB). The modes can include transverse electromagnetic (TEM) modes such as TEM₀₀, TEM₁₀, and TEM₀₁. The MMB is based on the electrical data that was sent. The MMB is coupled optically to an optical medium. The optical medium comprises a waveguide. The coupling optically can be accomplished using a grating coupler, a bent waveguide, or a mirror. The optical medium is further coupled to a mode-dependent optical element (MDOE). The MDOE decodes the MMB into the electrical data that was sent. The electrical data that was decoded is delivered to a second circuit which can be a second chiplet. The second circuit can be collocated within the first circuit. The second circuit can be located remotely from the first circuit. The sending, modulating, coupling, decoding, and delivering enable an optical link with modulation of VCSEL modes.

Disclosed is a system for transmitting data comprising: a first circuit, wherein the first circuit is coupled to a vertical-cavity surface-emitting laser (VCSEL); an optical medium, wherein light emitted from the VCSEL is coupled optically to the optical medium via an optical coupler; a mode-dependent optical element (MDOE), wherein the MDOE is further coupled to the optical medium; and a second circuit; wherein the system is configured to: send electrical data, by the first circuit, to the VCSEL; modulate a mode of the VCSEL, wherein the modulating includes emitting, by the VCSEL, a mode-modulated beam (MMB), wherein the MMB is based on the electrical data that was sent; couple optically the MMB to the optical medium; decode, by the MDOE, the MMB into the electrical data that was sent; and deliver the electrical data to the second circuit.

The system 700 includes a first circuit 710, wherein the first circuit is coupled to a vertical-cavity surface-emitting laser (VCSEL) 712. The first circuit can be a circuit within a chip, a core, a chiplet, an SoC, a wafer, an interposer, etc. The first circuit can comprise a processor, chiplet, multi-core processor, memory controller, memory chip such as DDR or HBM, I/O chip, AI accelerator, switching chip, and so on. The first circuit can comprise a chiplet within a plurality of chiplets. The chiplets can include processor chiplets, memory chiplets, AI accelerator chiplets, switching chiplets, I/O chiplets, and the like bonded to a PWSI. The VCSEL can include a VCSEL within a plurality of VCSELs. Other surface-emitting light sources can also be used. In a usage example, a surface-emitting light source can include a light emitting diode (LED), a laser diode (LD), and so on. The system 700 includes an optical medium 714, wherein light emitted from the VCSEL is coupled optically to the optical medium via an optical coupler. The optical medium can include an optical fiber, an optical waveguide, and so on. In a usage example, the optical medium can include a modulated mode-maintaining fiber. Various optical couplers can be used to optically couple a mode-modulated beam (MMB) to the optical element. The optical coupler can comprise a grating coupler. In embodiments, the coupling optically is accomplished by a grating coupler. The grating coupler can include a periodic grating that can transfer the MMB with low loss into the optical medium. The optical coupler can comprise a mirror. In other embodiments, the coupling optically is accomplished by a mirror. In a usage example, the mirror can include a nano-imprint lithography mirror. In further embodiments, the coupling optically includes angling the MMB that was emitted by the VCSEL, wherein the angling is based on a micro-optical element (MOE). The angling the MMB can be used to complement an angle associated with the coupling the PMB to the optical medium.

The system 700 includes a mode-dependent optical element (MDOE) 716, wherein the PDOE is further coupled to the optical medium. The MDOE can separate different modes of light from the MMB emitted by the VCSEL. The separated modes of light are decoded into electrical data that was sent by the first circuit. The MDOE can accomplish decoding based on a plurality of decoding techniques. In embodiments, the MDOE comprises a micro lens. The micro lens can include a micro lens within a micro lens array. The micro lens array can split the MMB into multiple beamlets, where each beamlet is based on a light mode. In embodiments, the MDOE comprises a coupling optically is based on a coupling optically is based on a grating coupler. The coupling optically is based on a grating coupler separates different modes in the MMB from each other. The separated modes of light can be sent to optical receivers that convert the optical data to electrical data. In a usage example an optical receiver can comprise a photodiode. In another embodiment, the MDOE comprises a mode filter. A mode filter can enable passage of light with a mode that is compatible with the mode filter while substantially filtering out light with modes that are incompatible with the mode filter. In further embodiments, the MDOE comprises a mode multiplexor (MMUX). The MMUX separates light that includes two or more modes. In a usage example, the received light is separated into two or more beams where each beam is based on a single mode. In embodiments, the decoding includes separating, by a mode beam splitter (MBS), the MMB into at least two single mode optical signals. In a usage example, the mode beam splitter can reflect light associated with a first mode and transmit light associated with a second mode. In embodiments, the MBS is based on a coupling optically is based on a grating coupler. The coupling optically is based on a grating coupler can be based on various grating configurations. In embodiments, the coupling optically is based on a grating coupler comprises a two dimensional grating pattern. The system 700 includes a second circuit 718. The second circuit can be substantially similar to the first circuit or substantially different. The second circuit can be a circuit within a chip, a core, a chiplet, an SoC, a wafer, an interposer, etc. The second circuit can comprise a processor, chiplet, multi-core processor, memory controller, memory chip such as DDR or HBM, I/O chip, AI accelerator, switching chip, and so on. The second circuit can comprise a second chiplet within a plurality of chiplets. In a usage example, the first circuit and the second circuit comprise artificial intelligence (AI) accelerators. In a second usage example, the first circuit and the second circuit comprise switching chiplets.

The system 700 includes a sending component 720. The sending component 720 is configured to send electrical data, by the first circuit, to the VCSEL. The data can be sent by the first circuit to the VCSEL using one or more of wires, interconnect, metal layers, etc. The metal layers can include metal layers within a circuit board, a wafer, an interposer, and so on. The metal layers, which enable interconnection between and among circuits, chiplets, and other elements, can be fabricated on or within a circuit board, wafer, or interposer. Using the metal layers offers significant inter-chiplet communications speed advantages due to short wire lengths, and reduced “parasitics” such as resistance, capacitance, and inductance. The VCSEL can emit light based on the sent data. The emitted light represents the data as optical data. The emitted light can be modulated, where the modulated light includes a mode.

The system 700 includes a modulating component 730. The modulating component 730 is configured to modulate a mode of the VCSEL, wherein the modulating includes emitting, by the VCSEL, a mode-modulated beam (MMB), wherein the MMB is based on the electrical data that was sent. The MMB can include a beam with a plurality of light modes. In a usage example, the MMB can include two modes, where one mode represents a logic one and the second mode represents a logic zero. In another usage example, two modes can represent two different serial data streams. The first circuit can send data to other surface-emitting light sources that can be modulated such as light emitting diodes (LEDs), laser diodes (LDs), and the like. The MMB can include modes such as transverse electromagnetic (TEM) modes. The TEM modes can include TEM₀₀, TEM₁₀, and TEM₀₁.

The system 700 includes a coupling optically component 740. The coupling optically component 740 is configured to couple optically the MMB to the optical medium. The optical medium can include a low loss optical medium appropriate for sending the MMB. In embodiments, the optical medium comprises a waveguide. The optical medium can also include an optical fiber. In a usage example, the optical medium comprises a mode maintaining fiber. In embodiments, the optical medium comprises a single mode fiber. The coupling optically is accomplished using an optical coupler. A variety of optical couplers can be used as described above. In further embodiments, the coupling optically includes angling the MMB that was emitted by the VCSEL, wherein the angling is based on a micro-optical element (MOE). The angling the PMB can be used to complement an angle associated with the coupling the PMB to the optical medium. In a usage example, the PMB emitted by VCSEL can be angled to 9.74 degrees prior to being directed at a mirror. The mirror, such as a crystallographic etched mirror, can include an angle of 54.74. The angling the PMB compensates for the mirror angle deviation from 45 degrees, thereby enabling coupling the PMB to a waveguide at an angle substantially normal to an entrance aperture of the waveguide. The angling can also compensate for variations in a wafer or interposer across the surface of the wafer or interposer.

The system 700 includes a decoding component 750. The decoding component 750 is configured to decode, by the MDOE, the MMB into the electrical data that was sent. The MDOE can separate distinct modes of light from the MMB. The modes can be based on TEMs such as TEM₀₀, TEM₁₀, and TEM₀₁ discussed above or other TEMs. The separated modes of light, which are based on optical data, can be decoded into electrical data. The decoded electrical data is the data that was sent by the first circuit. The MDOE can accomplish decoding based on a plurality of decoding technique, such as a coupling optically is based on a grating coupler, a mode filter, a mode mux, and so on.

The system 700 includes a delivering component 760. The delivering component 760 is configured to deliver the electrical data to the second circuit. The electrical data can be delivered by the delivering component to the second circuit using wire, interconnect, metal layers, and so on. The metal layers can include metal layers within a circuit board, a wafer, an interposer, and the like. The metal layers, which enable interconnection between and among circuits, chiplets, and other elements, can be fabricated on or within a circuit board, wafer, chip, or interposer. As was the case for sending the data from the first circuit to the VCSEL, using the metal layers offers significant inter-chiplet communications speed due to short wire lengths, and reduced “parasitics” such as resistance, capacitance, and inductance. The second circuit can process the delivered data, forward the delivered data, etc.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for transmitting data comprising:
sending electrical data, by a first circuit, to a vertical-cavity surface-emitting laser (VCSEL);
modulating a mode of the VCSEL, wherein the modulating includes emitting, by the VCSEL, a mode-modulated beam (MMB), wherein the MMB is based on the electrical data that was sent;
coupling optically the MMB to an optical medium, wherein the optical medium is further coupled to a mode-dependent optical element (MDOE);
decoding, by the MDOE, the MMB into the electrical data that was sent; and
delivering the electrical data that was decoded to a second circuit.

2. The method of claim 1 wherein the VCSEL comprises an inverted aperture VCSEL.

3. The method of claim 1 wherein the modulating comprises altering current to the VCSEL.

4. The method of claim 1 wherein the VCSEL comprises a multimodal VCSEL.

5. The method of claim 4 wherein the multimode VCSEL supports one or more high order transverse modes.

6. The method of claim 5 wherein the modulating comprises switching between a lower order transverse mode and a high order transverse mode within the one or more high order transverse modes.

7. The method of claim 6 wherein the switching is based on current injection.

8. The method of claim 6 wherein a fundamental mode of the VCSEL comprises a higher order mode than a non-fundamental mode.

9. The method of claim 8 wherein the switching is based on current injection.

10. The method of claim 1 wherein the MDOE comprises a micro lens.

11. The method of claim 1 wherein the MDOE comprises a mode filter.

12. The method of claim 1 wherein the MDOE comprises a grating coupler.

13. The method of claim 1 wherein the MDOE comprises a mode multiplexor (MMUX).

14. The method of claim 13 wherein the decoding includes separating, by a mode beam splitter (MBS), the MMB into at least two single mode optical signals.

15. The method of claim 14 wherein the MBS is based on a grating coupler.

16. The method of claim 15 wherein the grating coupler comprises a two dimensional grating pattern.

17. The method of claim 15 further comprising interpreting each single mode optical signal within the at least two single mode optical signals, by a unique photodiode, to an electrical signal, wherein the interpreting results in at least two electrical signals.

18. The method of claim 17 further comprising assembling the at least two electrical signals into a single electrical signal, wherein the single electrical signal comprises the electrical data that was sent.

19. The method of claim 1 wherein the optical medium comprises a waveguide.

20. The method of claim 19 wherein the coupling optically is based on a grating coupler.

21. The method of claim 20 further comprising angling the MMB that was emitted by the VCSEL, wherein the angling is based on a micro-optical element (MOE).

22. The method of claim 19 wherein the coupling optically is based on a mirror.

23. The method of claim 1 wherein the optical medium comprises a single mode fiber.

24. The method of claim 1 wherein the first circuit comprises a first chiplet and the second circuit comprises a second chiplet.

25. An apparatus for transferring data comprising:
a first circuit, wherein the first circuit sends electrical data to a vertical-cavity surface-emitting laser (VCSEL), and wherein the VCSEL emits a mode-modulated beam (MMB);
an optical medium, wherein the MMB is coupled optically to the optical medium via an optical coupler;
a mode-dependent optical element (MDOE), wherein the MDOE is further coupled to the optical medium, wherein the MDOE decodes the MMB into the electrical data that was sent; and
a second circuit, wherein the second circuit receives the electrical data that was sent.

26. The apparatus of claim 25 wherein the VCSEL comprises a multimodal VCSEL.

27. The apparatus of claim 25 wherein the first circuit comprises a first chiplet, wherein the second circuit comprises a second chiplet, wherein the first chiplet, the second chiplet, and the VCSEL are within a plurality of chiplets bonded to a front side of a photonic wafer-scale interposer (PWSI), wherein the PWSI includes a plurality of waveguides and wherein the optical medium comprises a waveguide within the plurality of waveguides.

28. A system for transferring data comprising:
a first circuit, wherein the first circuit is coupled to a vertical-cavity surface-emitting laser (VCSEL);
an optical medium, wherein light emitted from the VCSEL is coupled optically to the optical medium via an optical coupler;
a mode-dependent optical element (MDOE), wherein the MDOE is further coupled to the optical medium; and
a second circuit;
wherein the system is configured to:
send electrical data, by the first circuit, to the VCSEL;
modulate a mode of the VCSEL, wherein the modulating includes emitting, by the VCSEL, a mode-modulated beam (MMB), wherein the MMB is based on the electrical data that was sent;
couple optically the MMB to the optical medium;
decode, by the MDOE, the MMB into the electrical data that was sent; and
deliver the electrical data to the second circuit.
